(19) United States
(12) Patent Application Publication
(10) Pub. No.: US 2025/0311142 A1
(43) Pub. Date: Oct. 2, 2025

(54) COOLING ASSEMBLIES FOR HANDHELD DEVICES

(71) Applicant: Adeia Semiconductor Bonding Technologies Inc., San Jose, CA (US)

(72) Inventor: Belgacem Haba, Saratoga, CA (US)

(21) Appl. No.: 18/751,696

(22) Filed: Jun. 24, 2024

Related U.S. Application Data
(60) Provisional application No. 63/571,898, filed on Mar. 29, 2024.
(60) Provisional application No. 63/651,853, filed on May 24, 2024.

(51) Int. Cl. H05K 7/20; H04M 1/02

(52) U.S. Cl. CPC H05K 7/20163; H04M 1/026; H05K 7/20172

(57) ABSTRACT

Embodiments herein provide for cooling assemblies provided within a handheld device. In one embodiment, a handheld device comprises a casing, a device package, and a cooling assembly. The casing has an air inlet opening and an air outlet opening disposed therethough. The casing volume is split into a device volume and a cooling volume, the cooling volume separated from the device volume by a dividing surface, and the cooling volume includes the air inlet opening and the air outlet opening. The device package is disposed within the device volume, and the cooling assembly is attached to the casing wall and disposed within the cooling volume. The cooling assembly comprises a vibrational membrane arranged to create a cooling airflow within the cooling volume by drawing air through the air inlet opening.

### CROSS-REFERENCE TO RELATED APPLICATIONS

This application claims the benefit of U.S. Provisional Patent Application No. 63/571,898, filed Mar. 29, 2024, and U.S. Provisional Patent Application No. 63/651,853, filed May 24, 2024, both of which are incorporated by reference herein in their entireties.

### FIELD

The present disclosure relates to cooling for handheld devices, and in particular, cooling systems integrated into handheld and mobile devices.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks and each of those high performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc. have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s); and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contribute to the system thermal resistance accumulatively along the heat transfer paths and raise chip junction temperatures from the ambient.

Such cooling systems can suffer from reduced cooling efficiency due to the design and manufacture of system components. Some devices, for various reasons, cannot employ fan-based cooling, and thus the passive heat dissipation from such devices provides an upper limit of device processing power and device heat and power dissipation. In an effort to reduce the operating temperature of such devices, whilst enabling an increase in processing power thereof, it is desirable to increase the heat dissipation envelope. Accordingly, heat may be dissipated from such devices by passing heated air out of the device.

Accordingly, there exists a need in the art for improved energy-efficient cooling systems, by reducing system thermal resistance, and methods of manufacturing the same.

### SUMMARY

Embodiments herein provide integrated cooling assemblies within handheld devices.

Advantageously, the integrated cooling assemblies deliver appropriate cooling to a semiconductor device within a handheld device so as to obtain effective cooling thereof.

One general aspect includes handheld device comprising a casing, a device package and a cooling assembly. The casing has an air inlet opening and an air outlet opening disposed therethough, the casing comprising a display side, a backside opposite the display side, and sidewalls connecting the display side and the backside to collectively define a casing wall having a casing volume therewithin. The casing volume is split into a device volume and a cooling volume, and the cooling volume is separated from the device volume by a dividing surface, the cooling volume including the air inlet opening and the air outlet opening. The device package is disposed within the device volume, the cooling assembly is attached to the casing wall and disposed within the cooling volume. The cooling assembly comprises a vibrational membrane arranged to create a cooling airflow within the cooling volume by drawing air through the air inlet opening. The device package includes a thermal interface material, wherein the thermal interface material is in thermal contact with the device package and the dividing surface, and the dividing surface is in thermal contact with the cooling airflow.

Implementations of the device package according to the first general aspect may include one or more of the following features. In one embodiment, the air inlet opening, the cooling assembly, and the air outlet opening collectively define a cooling airflow path. In some embodiments, the cooling assembly includes a further air inlet aligned with the air inlet opening in the casing. In some embodiments, the cooling assembly includes a further air outlet in fluid communication with the casing volume. In some embodiments, the vibrational membrane comprises more than one vibrational membrane. In some embodiments, the cooling assembly is formed as part of the casing.

A second general aspect includes handheld device comprising a casing, a device package, and a cooling assembly, wherein the casing has an air inlet opening and an air outlet opening disposed therethough, the casing comprising a display side, a backside opposite the display side, and sidewalls connecting the display side and the backside to collectively define a casing wall having a casing volume therewithin. The casing volume is split into a device volume and a cooling volume, the cooling volume separated from the device volume by a divider, the device volume including the air inlet opening and the cooling volume including the air outlet opening. The cooling volume is disposed within the device volume, such that the divider substantially encloses the cooling volume within the device volume, and the cooling assembly is disposed within the cooling volume and is in thermal contact with the divider. The cooling assembly comprises a vibrational membrane. The device package is disposed within the device volume, the device package comprises a heat spreader in thermal contact with the divider, and the cooling volume is in fluid communication with the device volume by way of at least one opening in the divider, and the air outlet opening provides a fluid pathway out of the casing volume. The cooling assembly is arranged to create a cooling airflow within the casing volume by drawing air through the air inlet opening, through the at least one opening in the divider and through the air outlet opening, to cool the device package.

A third general aspect includes a handheld device comprising a casing, a device package, and a cooling assembly, wherein the casing has an air inlet opening and an air outlet opening disposed therethough, the casing comprising a display side, a backside opposite the display side, and sidewalls connecting the display side and the backside to collectively define a casing wall having a casing volume therewithin. The device package and the cooling assembly are disposed within the casing volume. The cooling assembly is attached to the casing wall and disposed within the casing volume, wherein the cooling assembly comprises a vibrational membrane arranged to create a cooling airflow within the casing volume by drawing air through the air inlet opening, and the device package includes a heatsink attached to and in thermal contact therewith. The heatsink is in thermal contact with the cooling airflow.

A fourth general aspect includes a method of cooling a handheld device, the method comprising operating at least one device package within the handheld device, providing at least one vibrational membrane to within the handheld device, creating a cooling airflow by way of the at least one vibrational membrane, directing the cooling airflow over the at least one device package within the handheld device to cool the at least one device package, continuing to operate the at least one device package within the handheld device, continuing to create the cooling airflow by way of the at least one vibrational membrane, and continuing to direct the cooling airflow over the at least one device package within the handheld device to cool the at least one device package.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A illustrates a device package with an external heat sink;

FIG. 1B is a schematic sectional view of an example handheld device including a cooling assembly having a vibrational membrane in accordance with embodiments of the disclosure;

FIG. 1C is a schematic sectional view of another example handheld device including a cooling assembly having a vibrational membrane in accordance with embodiments of the disclosure;

FIG. 2 is a schematic sectional view of another example handheld device including a cooling assembly having a vibrational membrane in accordance with embodiments of the disclosure;

FIG. 3 is a schematic view of a handheld device including a vibrational membrane in accordance with embodiments of the disclosure;

FIG. 4 is another schematic view of a handheld device including a vibrational membrane in accordance with embodiments of the disclosure;

FIG. 5A is a schematic sectional view of a vibrational membrane cooling arrangement to be used with embodiments of the disclosure;

FIG. 5B is another schematic sectional view of a vibrational membrane cooling arrangement to be used with embodiments of the disclosure;

FIG. 6A is a schematic view of a vibrational membrane, which may be used with some embodiments of the disclosure;

FIG. 6B is a schematic isometric view of vibrational membrane openings and helicoidal ribs, that may be used with embodiments of the disclosure;

FIG. 7 is a schematic sectional view of a further example handheld device having a vibrational membrane in accordance with aspects of the disclosure;

FIG. 8 is a schematic sectional view of another example handheld device having a vibrational membrane in accordance with aspects of the disclosure; and

FIG. 9 shows a method that can be used to cool a handheld device including cooling assemblies as described herein.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1^{st}) nonconductive feature directly bonded to another (2^{nd}) nonconductive feature, and ii) at least one (1^{st}) conductive feature directly bonded to another (2^{nd}) conductive feature, without any intervening adhesive. In some hybrid bonding embodiments, there are many 1^{st} conductive features, each directly bonded to a 2^{nd} conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element at via annealing at slightly higher temperatures (e.g., >100° C., >200° C., >250° C., >300° C., etc.).

As described below, air or a coolant fluid flowing through a cooling assembly which includes a vibrational membrane or vibrational may be used to control the temperature of semiconductor devices. The cooling assembly may direct air or fluid such that it flows across a back side of the semiconductor device, or across a heat spreader of the semiconductor device, such that the air or fluid flow absorbs heat and conducts heat away from the device.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. All of these fluids and fluid mixtures will alter the thermohydraulic and heat transfer properties by altering the temperatures where phase change occurs, as well as meeting design temperature and pressure conditions for the component being cooled or warmed and the thermal solution being deployed. Additionally, multiple combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or less in diameter. Silicon oxide microparticles may be used.

The volume concentration of these micro or nanoparticles may be less than 1%, less than 0.2%, or less than 0.05%. Depending upon the liquid and micro/nanoparticle type chosen for the cooling fluid, higher volume concentrations of 10% or less, 5% or less, or 2% or less may be used. The cooling fluids may also contain small amounts of glycol or glycols (e.g. propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using cooling fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In general, handheld mobile devices, such as smart phones, tablets, and the like are cooled passively. Such devices, for various reasons, cannot employ fan-based cooling, and thus the passive heat dissipation from such devices provides an upper limit of device processing power and device heat and power dissipation.

To reduce the operating temperature of such handheld devices whilst enabling an increase in processing power thereof, it is desirable to increase the heat dissipation envelope. Solutions which increase the overall temperature of the case of the device may present problems when the device is stored, for example, in a user's pocket.

Accordingly, the present disclosure provides systems and methods for dissipating heat from such a handheld device by passing heated air out of the device. The devices concerned are not limited to handheld devices, and may be applicable to any system requiring cooling and having an outer case. The present disclosure contemplates attaching cooling to a package or packages or elements within a device.

It is to be understood that the systems and methods as described herein are not limited to a handheld device such as a handheld phones, but may be applied to devices which cannot, or would be preferable not to, use conventional cooling or liquid cooling. It may be used in connection with laptops, and/or devices having relatively low processing power. Heated air may be pushed out of the outer shell of a device, with intake air drawn from outside the outer shell of the device.

A cooling assembly including a vibrational membrane may be a discrete component which is attached to a semiconductor device. In such a case, the cooling assembly may include a heat sink or contact plate which is arranged such that it may be attached to the backside or integrated heat spreader of a semiconductor device. In some cases, the cooling assembly may be arranged such that the vibrational membrane gives rise to an air or fluid flow which passes over the back side or integrated heat spreader of a semiconductor device in order to cool the semiconductor device.

In some cases, the cooling assembly may be integrated into the casing of a device or attached to the casing of a device such that the vibrational membrane, housed within the cooling assembly, gives rise to an air or fluid flow which passes over the back side or integrated heat spreader of a semiconductor device in order to cool the semiconductor device. The casing of the device may be formed of plastic, epoxy, metal, or any other suitable material. In cases where the cooling assembly is integrated into the casing of a device or attached to the casing of a device, the cooling assembly and vibrational membrane may arranged such that the air or fluid flow causes cool air or fluid to be drawn into the casing of the device, passed over the semiconductor device so as to cool the semiconductor device (by absorbing heat from the semiconductor device, and the warmed air to be passed out of the casing of the device).

The vibrational membrane within the cooling assembly may be actuated by way of a piezoelectric transducer or a magnetostrictive transducer, and such transducers may be implemented as microelectromechanical system (MEMS) devices.

A piezoelectric transducer may cause movement of the vibrational membrane as a result of the piezoelectric effect, that is to say the vibrational membrane, when attached to the piezoelectric transducer, moves because movement of the transducer is caused by application of a voltage to the piezoelectric transducer.

A vibrational membrane may take the form of a fan blade, elongate member, or the alike, and may be attached to a piezoelectric transducer such that oscillatory movement of the piezoelectric transducer gives rise to oscillatory movement of the vibrational membrane. The elongate member which forms the vibrational member may be longer than it is wide, i.e., it takes a rectangular shape. The piezoelectric transducer may be affixed to one of the opposing shorter sides of the elongate member, leaving the length of the elongate member and therefore the free end (which may be the other of the opposing shorter sides thereof) to oscillate.

The oscillatory movement of the vibrational membrane causes movement of the air. This movement of the air may be directed, in some cases by way of the casing of the cooling assembly, to give rise to airflow.

The vibrational member may be attached to a piezoelectric transducer at one end, which may be described as the driven end, and the distal end of the vibrational member, which may be described as the free end. The piezoelectric transducer, when activated, causes motion of the vibrational membrane, such that the free end oscillates to give rise to movement of the air.

In some cases, the cooling assembly may include more than one vibrational membrane, each attached to a transducer to generate movement thereof. In some cases, a plurality of vibrational membranes may each be attached to respective transducers to effect movement thereof. In some examples, the cooling assembly includes two vibrational membranes and associated transducers. In some examples, the cooling assembly includes more than two vibrational membranes and associated transducers. In some examples, the cooling assembly includes ten vibrational membranes and associated transducers. In some examples, the cooling assembly includes more than ten vibrational membranes and associated transducers.

In some examples, multiple vibrational membranes may be attached to, and actuated by, a single transducer.

The voltage required to affect movement of a piezoelectric transducer within a cooling assembly may be supplied through a connector attached to, or formed as part of, the piezoelectric transducer. In some cases, the cooling assembly may include control circuitry or other apparatus capable of varying the speed at which the vibrational membrane or membranes oscillates.

In general, for every one watt of electrical power supplied to the cooling assembly containing vibrational membranes, approximately five watts of heat energy may be dissipated.

The vibrational membrane or membranes described herein may be actuated by way of a piezoelectric transducer as described above, by a magnetostrictive transducer, or any other suitable transducer. A magnetostrictive transducer may, for example, consist of a large number of nickel, or any other magnetostrictive material, plates or layers. Such plates or layers may be arranged in parallel, with one edge of each plate or layer attached to a member or item to be vibrated. In the case of the present disclosure, such member or item may be a vibrational membrane or membranes.

To affect oscillation of the vibrational membrane, a coil of wire is placed around the magnetostrictive material. An electrical current is then supplied through the coil of wire. In doing so, a magnetic field is created which causes the magnetostrictive material to contract or elongate. This causes oscillation of the vibrational member, which in turn gives rise to movement of the air.

The movement of the air caused by the oscillation of a vibrational membrane or membranes as described herein may be used to provide cooling in handheld or portable devices.

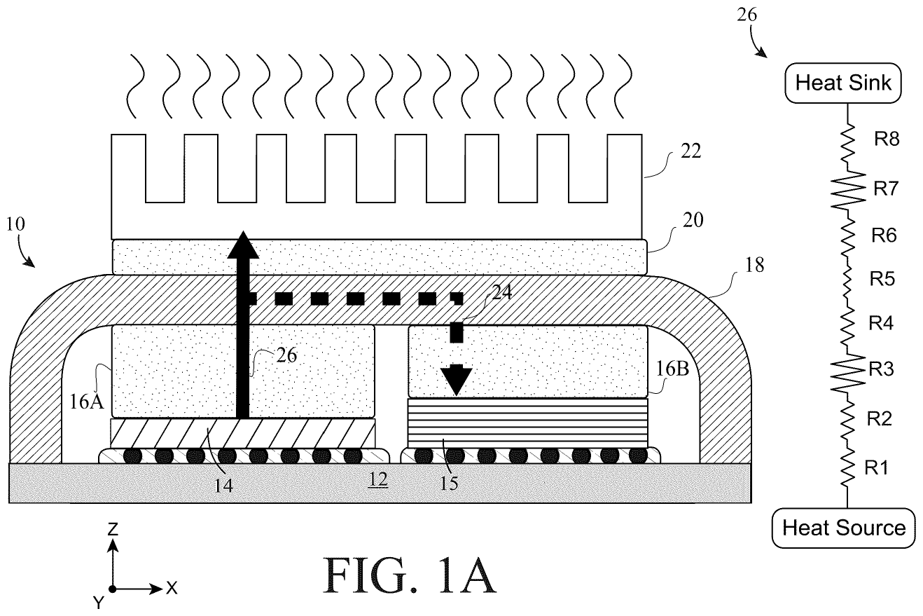

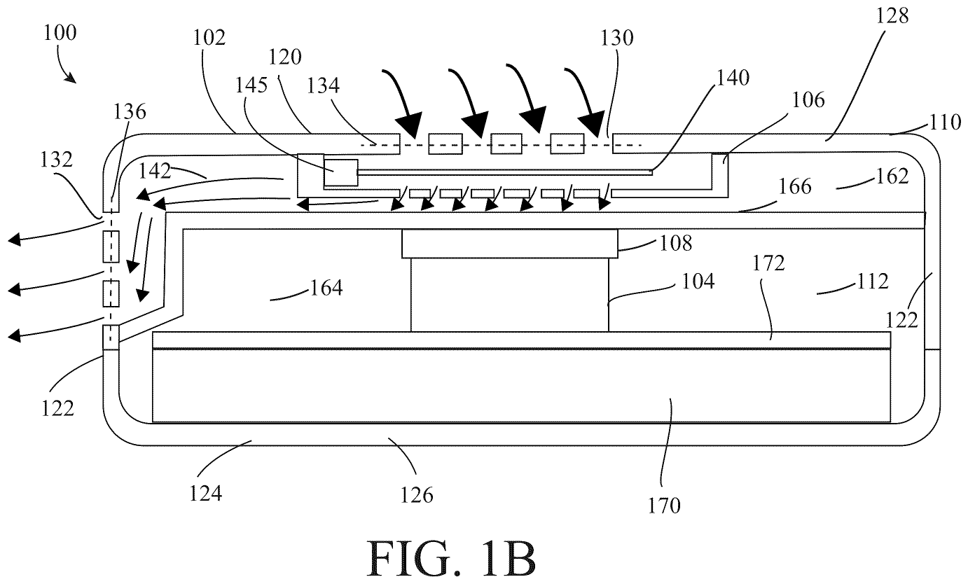

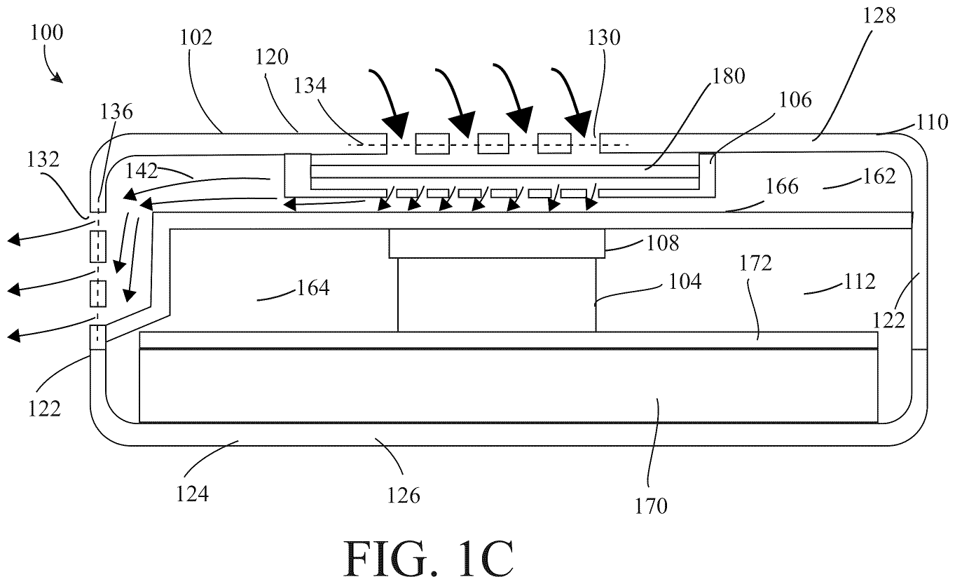

FIG. 1A is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and device stack 15 to the heat spreader 18. The device package 10 is thermally coupled to a heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1A is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirable transferred from the first device 14 having a high heat flux, such as a CPU or GPU, to the device stack 15 having low heat flux, such as memory, through the heat spreader 18.

For example, as shown in FIG. 1A, each device package component and the respective interfacial boundaries therebetween has a corresponding thermal resistance which forms heat transfer path 26 (illustrated by arrow 26 in FIG. 1A). The left-hand side of FIG. 1A illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. R1 of the first device 14 and R2, R4, R6, and R8 of the interfaces account for the remaining cumulative thermal resistance. Accordingly, embodiments herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures herein.

FIG. 1B shows a schematic view of a handheld device including a cooling assembly having a vibrational membrane. The handheld device 100 includes a casing 102, a device package 104, and a cooling assembly 106. The casing 102 may be formed of metal, plastic, or any other suitable material. The device package 104 may be a semiconductor device. The cooling assembly 106 may, as described below, be attached to the wall of the device 100.

The casing 102 has an air inlet opening 130 and an air outlet opening 132 disposed therethough. The casing 102 comprises a display side 120 which may include a display (e.g., an LCD display or an OLED display), a backside 124 opposite the display side 120, and sidewalls 122 connecting the display side 120 and the backside 124 to collectively define a casing wall 110 having a casing volume 112 therewithin. As can be seen in FIG. 1B, the air inlet opening 130 includes a gas-permeable membrane 134. Such a gas permeable membrane may allow the passage of gases but not permit the passage of liquids, such as water, therethrough and thus may be waterproof. As a result, air may be permitted to enter the cooling assembly 106 and pass through the casing 102 of the device 100 to allow cooling, but liquids such as water are prevented from entering the device to alleviate the risk of water damage to the device 100 occurring. Similarly, the air outlet opening 132 includes a gas-permeable membrane 136.

As shown in FIG. 1B, the casing volume 112 of the handheld device 100 is split into a device volume 164 and a cooling volume 162, where the cooling volume 162 is separated from the device volume 164 by a dividing surface 166. The dividing surface 166 may be made of metal, and as described below, is in thermal contact with the device package 104. Therefore, the dividing surface 166 may be formed of a material which is thermally transmissive. The cooling volume 162 further includes the air inlet opening 130 and the air outlet opening 132, such that air may pass into the cooling volume 162 through the air inlet opening 130 and out of the air outlet opening 132, through the cooling volume 162.

The device package 104 is disposed within the device volume 164. The cooling assembly 106 is attached to the casing wall 110 and disposed within the cooling volume 162, wherein the cooling assembly 106 comprises a vibrational membrane 140 arranged to create a cooling airflow 142 within the cooling volume 162 by drawing air through the air inlet opening 130.

The vibrational membrane 140 is attached to a transducer 145 to affect movement of the vibrational membrane 140. A driven end of the vibrational membrane 140 is attached to the transducer 145, with the free end of the vibrational membrane unconstrained to oscillate within the cooling assembly 106. Operation of the cooling assembly 106 may be affected by way of control circuitry (not shown in FIG. 1B). The transducer 145 may be a piezoelectric transducer or a magnetostrictive transducer, as described herein. The vibrational membrane 140 may be formed of a polymer material as an example.

The cooling assembly 106 may, in some examples, be formed as part of the casing wall 110 and thus be an integral part of the casing wall 110.

The device package 104 includes a thermal interface material 108, such that the thermal interface material 108 is in thermal contact with the device package 104 and the dividing surface 166. Therefore, heat energy may be transferred away from the device package 104, through the thermal interface material 108, and into the dividing surface 166, such that the device package 104 is cooled. To enable heat dissipation from the dividing surface 166, the dividing surface 166 is in thermal contact with the cooling airflow 142.

The air inlet opening 130, the cooling assembly 106, and the air outlet opening 132 collectively define a cooling airflow path, to enable fluid, in this case air, to be drawn in through the air inlet opening, through the cooling assembly 106, and out of the air outlet opening 132, over the dividing surface 166. As shown in FIG. 1B, the cooling airflow 142 within the casing volume 112 of the device 100 is within the cooling volume 162. As described above, in passing over the dividing surface 166, the cooling airflow 142 cools the dividing surface 166 which in turn cools the device package 104. In cooling the dividing surface 166, the cooling airflow 142 may cause a temperature differential between the cooling volume 162 and the device volume 164.

In FIG. 1B, the cooling volume 162 is not in fluid communication with the device volume 164 (i.e., fluid may not pass between the cooling volume 162 and the device volume 164). In some examples, the casing 102 may be formed of a first casing part 128 which includes the display side 120 of the casing 102 and a second casing part 126 which includes the backside 124 of the casing 102. The vibrational membrane may be configured to vibrate at a frequency from about 20 kHz to about 2 MHz.

The handheld device 100 may include a battery 170 which may be a lithium ion battery or other similar battery. The device package 104 of the handheld device may be attached to a PCB 172.

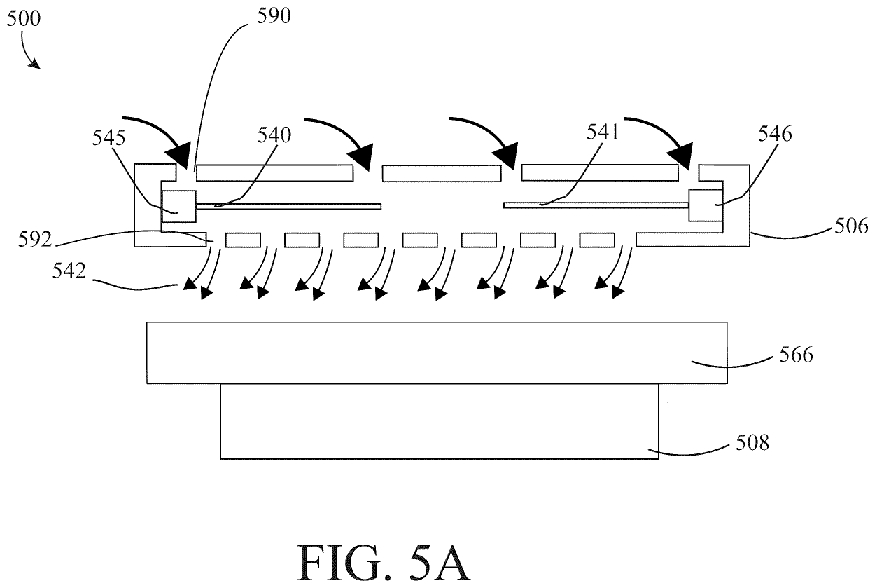

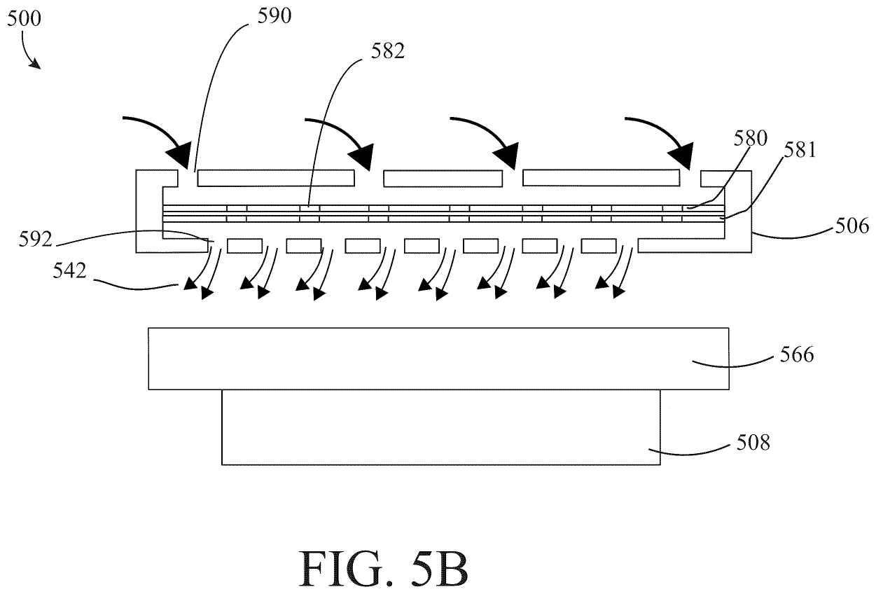

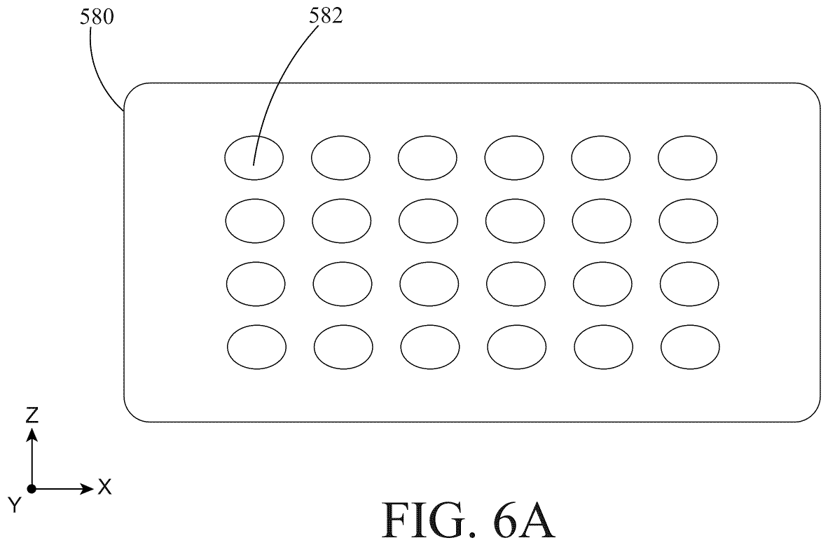

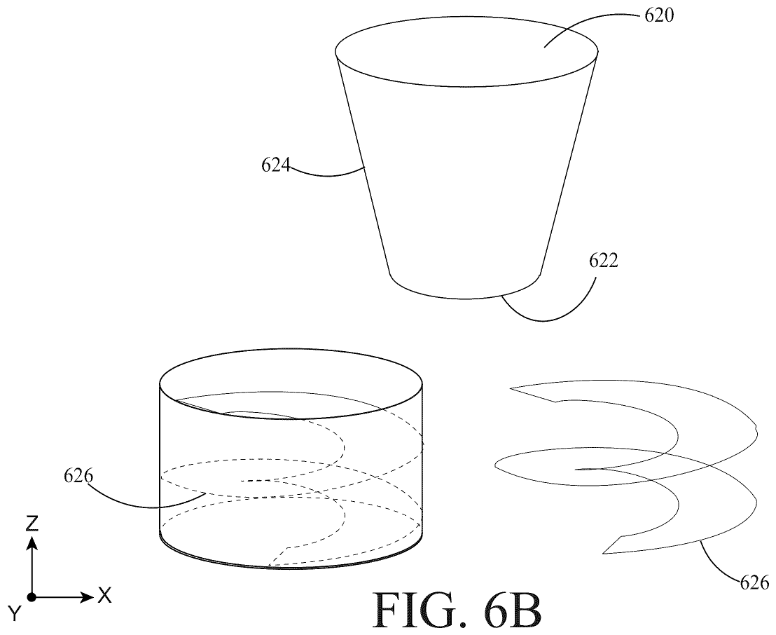

FIG. 1C shows a schematic sectional view of a handheld device which includes like features with those shown in FIG. 1B. The alternative vibrational membrane 180 shown in FIG. 1C replaces the vibrational membrane 140 and transducer 145 shown in FIG. 1B. The alternative vibrational membrane 180 of the handheld device 100 of FIG. 1C may take the form of an alternative vibrational membrane described later herein and with reference to FIGS. 5B, 6A, and 6B. In FIG. 1C, the alternative vibrational 180 membrane may be configured to direct compressed streams of gas out of the cooling assembly 106 towards the dividing surface 166 to cool the device package 104.

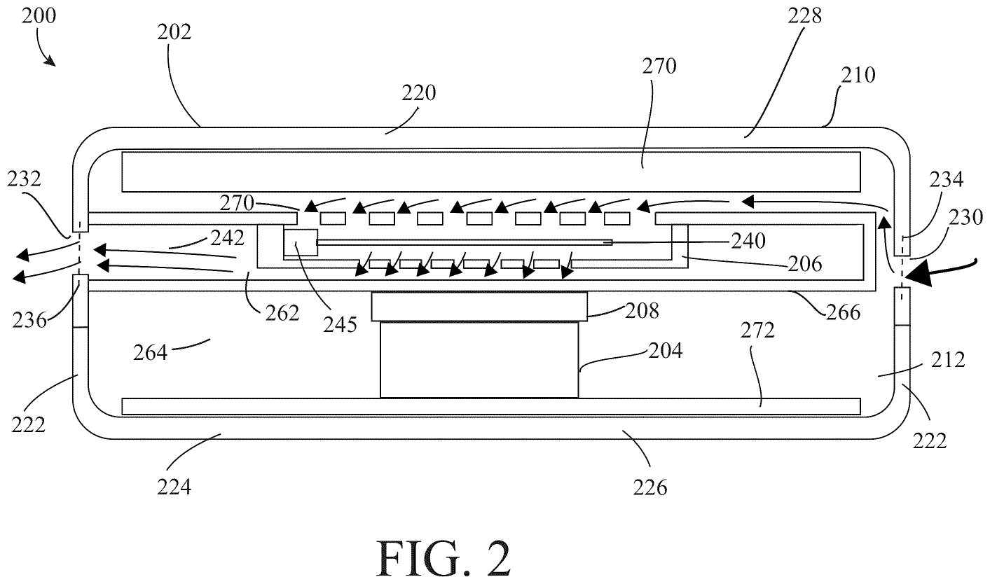

FIG. 2 shows a schematic sectional view of another example handheld device including a cooling assembly having a vibrational membrane. The handheld device 200 has a casing 202, a device package 204, and a cooling assembly 206. In a similar way to that described in connection with FIGS. 1A and 1B above, the casing 202 has an air inlet opening 230 and an air outlet opening 232 disposed therethough. The casing 202 comprises a display side 220, a backside 224 opposite the display side 220, and sidewalls 222 connecting the display side 220 and the backside 224 to collectively define a casing wall 210 having a casing volume 212 therewithin.

Similar to FIGS. 1B and 1C, the casing volume 212 of the handheld device 200 is split into a device volume 264 and a cooling volume 262, where the cooling volume 262 is separated from the device volume 264 by a divider 266. The device volume 264 includes the air inlet opening 230 and the cooling volume 262 including the air outlet opening 232. The divider 266 differs from the divider 166 of FIGS. 1B and 1C in that the cooling volume 262 is disposed within the device volume 264, such that the divider 266 substantially encloses the cooling volume 262 within the device volume 264, and the cooling assembly 206 is disposed within the cooling volume 262 and is in thermal contact with the divider. The arrangement shown in FIG. 2 may enable the overall size of the handheld device 200 to be reduced, because the cooling assembly 206 is encased within the middle of the casing 202 of the handheld device 200.

In a similar way to that shown in FIGS. 1B and 1C, the casing 202 may be formed of a first casing part 228 which includes the display side 220 of the casing 202 and a second casing part 226 which includes the backside 224 of the casing 202.

The cooling assembly 206 comprises a vibrational membrane 240 similar to that described in connection with FIG. 1B above, and includes a transducer 245 attached to one end of the vibrational membrane 240 in a similar way to that described in connection with FIG. 1B.

The device package 204 is disposed within the device volume 264. The device package 204 comprises a heat spreader 208 in thermal contact with the divider 266. The cooling volume 262 is in fluid communication with the device volume 264 by way of at least one opening 270 in the divider 266, and the air outlet opening 232 provides a fluid pathway out of the casing volume 212. The cooling assembly 206 is arranged to create a cooling airflow 242 within the casing volume 212 by drawing air through the air inlet opening 230, through the at least one opening 270 in the divider 266 and through the air outlet opening 232, to cool the device package 204.

Similar to FIGS. 1B and 1C above, the cooling airflow 242 may cause a temperature differential between the device volume 264 and the cooling volume 262, by way of the cooling airflow 242 passing over the divider 266. In some examples, the casing 102 may be formed of a first casing part 128 which includes the display side 120 of the casing 102 and a second casing part 126 which includes the backside 124 of the casing 102. The air inlet 230 and the air outlet 232, in a similar way to that described in connection with FIGS. 1B and 1C above, may both include gas-permeable membranes 234, 236. The gas-permeable membranes 234, 236 may be waterproof. The vibrational membrane 240 may be configured to vibrate at a frequency from about 20 kHz to about 2 MHz.

The handheld device 200 may include a battery 270 which may be a lithium ion battery. The device package 204 of the handheld device may be attached to a PCB 272.

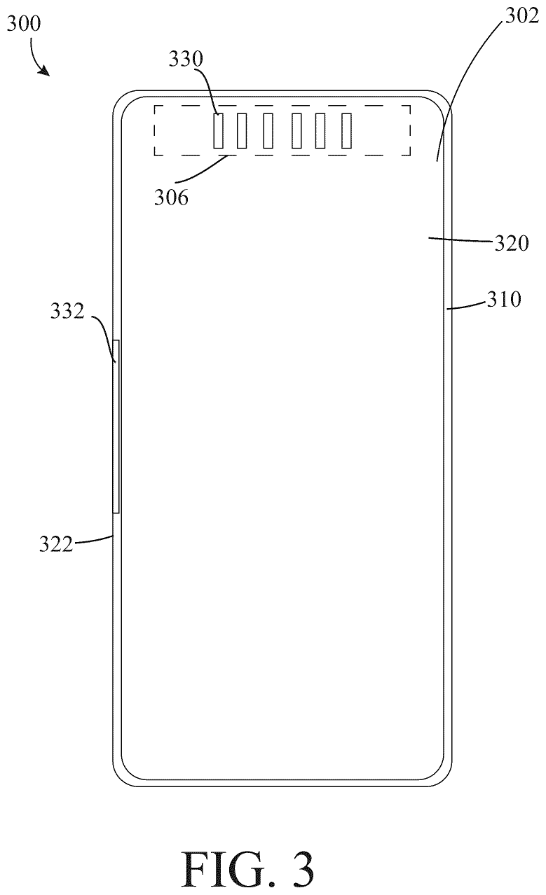

FIG. 3 shows a schematic view of a handheld device including a vibrational membrane. The handheld device 300 includes a casing 302, a cooling assembly 306 shown in phantom within the device, a casing wall 310, and a display side 320 of the device 300. The device casing 302 further includes sidewalls 322. Air inlet 330 and air outlet 332 are similar to the air inlets and outlets described in connection with FIGS. 1B, 1C and 2.

The handheld device 300 may be a handheld communications device 300 such as a smartphone. The air inlet opening 330 may be formed on the display side 320 of the casing 302. The air outlet opening 332 may be formed in a sidewall 322 of the device 300.

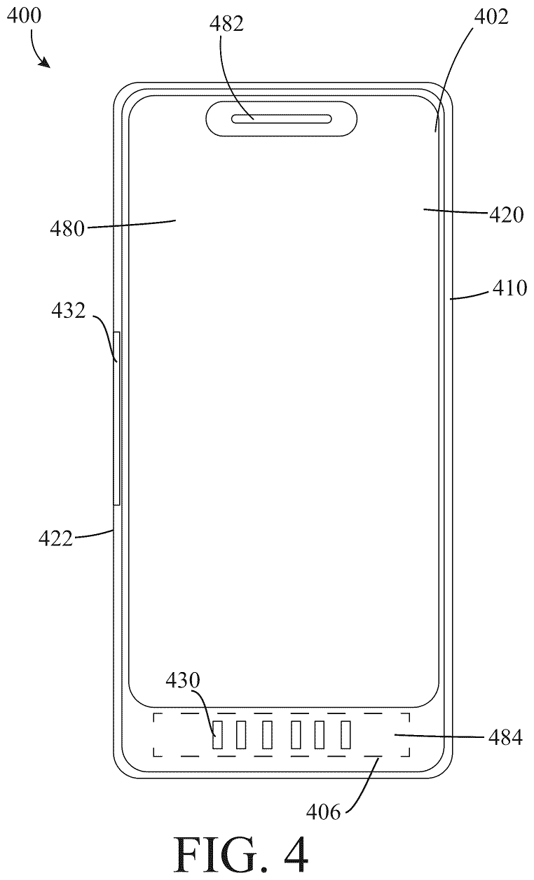

FIG. 4 shows a schematic view of a handheld device including a vibrational membrane. The handheld device 400 includes a casing 402, a cooling assembly 406 shown in phantom on the display side 420 of the device behind air inlet 430 which is also a microphone 484, a display 480 and a speaker 482 within the display 480 of the device 400. The handheld device 400 further includes a casing wall 410, an air outlet 432, and sidewalls 422. The air inlet of the cooling assembly 406 may draw air in from the microphone 484 opening of the display side 420 of the device 400.

Operation of the cooling assemblies 306, 406 of devices 300, 400 shown in FIGS. 3 and 4 is similar to that described in connection with FIGS. 1B, 1C, and 2 above.

The handheld device 400 of FIG. 4 may be a handheld communications device such as a smartphone. The air inlet opening 430 may be formed on the display side 420 of the casing 402. The air outlet opening 432 may be formed in a sidewall 422 of the device 400.

In the case that the handheld device 400 is a smartphone, the handheld device 400 further includes a display 480, a speaker 482, and a microphone region 484, and the microphone region 484 may include the air inlet opening 430 and a microphone.

FIG. 5A shows a schematic sectional view of a vibrational membrane cooling arrangement similar to that shown as part of handheld devices 100, 200 of FIGS. 1B and 2. The cooling arrangement 500 of FIG. 5A includes a cooling assembly 506 which includes two vibrational membranes 540, 541, each connected to a respective transducer. As can be seen in FIG. 5A, a first vibrational membrane 540 is attached to, and capable of being driven by, a first transducer 545. A second vibrational membrane 541 is attached to, and capable of being driven by, a second transducer 546. In some embodiments, only one vibrational membrane 540, 541 may be present. Air may be drawn into the cooling assembly 506 by way of a further air inlet 590. This further air inlet may be aligned with an air inlet opening in the casing of a handheld device. Air passes out of the cooling assembly 506 by way of a further air outlet 592. This further air outlet may be in fluid communication with the casing volume of a handheld device. Air flows out of the cooling assembly 506, and is shown in FIG. 5 as airflow 542.

The airflow 542 is caused by oscillatory movement, or vibration, of the vibrational membranes 540, 541 shown in FIG. 5A. The oscillatory movement of the vibrational membranes draws air into the cooling assembly 506, through the further air inlet 590, past the vibrational membranes 540, 541, and out of the cooling assembly 506 through the further air outlet 592. In the same way as that described above, the transducers 545, 546 may be driven by control circuitry (not shown) to affect movement of the vibrational membranes 540, 541.

The cooling arrangement 500 may be affixed to, or formed as part of, the casing 102, 202 of the handheld devices 100, 200 of FIGS. 1B and 2 described herein.

FIG. 5A shows the cooling assembly 506 having two vibrational membranes 540, 541. It is to be understood that one vibrational membrane 540 could be used, or more than two vibrational membranes could be used.

FIG. 5B shows a cooling assembly 500 which is similar to that shown in FIG. 5A. The alternative vibrational membranes 580, 581 shown in FIG. 5B replace the first and second vibrational membranes 540, 541 and first and second transducers 545, 546 shown in FIG. 5A. The alternative vibrational membranes 580, 581 of the cooling assembly 500 of FIG. 5B may take the form of an alternative vibrational membrane which is configured to direct compressed streams of gas out of the cooling assembly 506 and towards a device package to be cooled, in this case the heat spreader 566 and semiconductor device 508.

The cooling assembly 506 of FIG. 5B is divided into an upper fluid volume and a lower fluid volume, and the lower fluid volume is in fluid communication with the upper fluid volume through a one or more openings 582 in the or each alternative vibrational membrane 580, 581. An example of such an alternative vibrational membrane 580, 581 is shown in FIG. 6A described below. The openings 582 provide a means for fluid to flow between the upper fluid volume and the lower fluid volume.

FIG. 5B shows the cooling assembly 506 having two alternative vibrational membranes 580, 581 each having openings 582. It is to be understood that one alternative vibrational membrane 580 could be used, or more than two alternative vibrational membranes could be used.

FIG. 6A shows an alternative vibrational membrane 580 having plurality of openings 582 which may be arranged in rows and/or columns of rectangular, circular, oval, hexagonal or any other shaped openings. Typically, the sharp corners in these holes are to be avoided for high flow applications.

With reference to FIG. 5B, an example flow path of fluid through the upper fluid volume and the lower fluid volume may be as follows:
1. fluid enters the upper fluid volume through the further air inlet 590;
2. fluid flows from the upper fluid volume to the lower fluid volume through the openings 582 of the at least one alternative vibrational membrane 580, 581 and out of the cooling assembly 506;
3. fluid flows across a heat spreader 566 of a semiconductor device 508 and absorbs heat generated by the semiconductor device 508.

In some embodiments, the or each vibrational membrane 580, 581 may comprise an actuator and/or a transducer that converts an electrical input signal, received from control circuitry, into linear physical motion thus generating sonic vibrations. Each alternative vibrational membrane 580, 581 may vibrate at a frequency from about 20 kHz to about 2 MHz. This frequency range may be referred to as ultrasonic frequency. In embodiments where the fluid is a gas (e.g., atmospheric air or nitrogen, as discussed above), as the gas enters the cooling arrangement 506 via the further inlet openings 590, the gas is directed towards the semiconductor device 508 to be cooled via the or each alternative vibrational membrane 580, 581. As the gas passes through the openings of the or each alternative vibrational membrane 580, 581, the gas becomes compressed due to the or each oscillating alternative vibrational membrane 580, 581 and provides cooling of the semiconductor device 508. That is, the compressed gas impinges directly on the heat spreader 566 of the semiconductor device 506 to provide effective cooling thereof by means of pulsating jet streams of gas. It will be understood that liquid may be used instead of gas in certain embodiments.

FIG. 6B is a schematic isometric view of the alternative vibrational membrane openings 582, according to some embodiments. Here, the one or more openings 582 of the alternative vibrational membrane 580 may form conduits, whereby each conduit is defined by a first opening 622 in the first surface, a second opening 620 in the second surface, and a sidewall 624 extending between the first and second openings 620, 622. As shown in FIG. 6B, the conduits have a circular cross-section. The conduit may have a length in the Z-axis direction equal to or greater than a thickness of the vibrational membrane 580 in the Z-axis direction.

In some embodiments, the sidewalls 624 of the plurality of openings (e.g., conduits) may be funnel shaped (e.g., conical) such that a cross-section of an upper opening facing the further air inlet openings 590 is greater than a cross-section of a lower opening facing the further air outlet openings 592. That is, a cross-sectional width of the second opening 620 in the X-axis direction may be greater than a cross-sectional width of the first opening 622 in the X-axis direction. The funnel shaped sidewalls 624 accelerate the flow of fluid as the fluid flows through the openings. The accelerated flow focuses compressed fluid streams towards the further air outlet openings 592 and toward the semiconductor device 506.

The sidewalls may comprise helicoid ribs 626, as illustrated in FIG. 6B. The helicoid ribs 626 generate a vortex in fluid flowing from the upper fluid volume (e.g., the fluid cavity) to the lower fluid volume. That is, as fluid flows through the plurality of openings 582, the helicoid ribs 626 guide the fluid in a downward circular motion thus generating a vortex in the fluid. The fluid vortex induces massive stirring in the fluid flow, and enhancing heat transfer from the semiconductor device 506 to the fluid.

In some embodiments, the vibrational membranes and alternative vibrational membranes 540, 541, 580, 581 may be controlled either by a connection to control circuitry located on the semiconductor device or by a connection to external control circuitry.

As described above, example transducers which may be used to vibrate the vibrational membranes and alternative vibrational membranes 540, 541, 580, 581 include: magnetostrictive transducers and piezoelectric transducers. Furthermore, such transducers may be implemented as MEMS devices.

Beneficially, the improved heat transfer effects provided by the cooling arrangement 506 facilitate an increased power density of the semiconductor device 508.

Overall performance of the semiconductor device 508 may be improved due to the enhanced cooling properties provided by the or each vibrational membrane or alternative vibrational membrane 540, 541, 580, 581.

In some embodiments, each alternative vibrational membrane 580, 581 may be formed from silicon, polysilicon, doped polysilicon, polymers, lithium niobate, lithium tantalate, quartz, acoustic membrane metamaterials, for example.

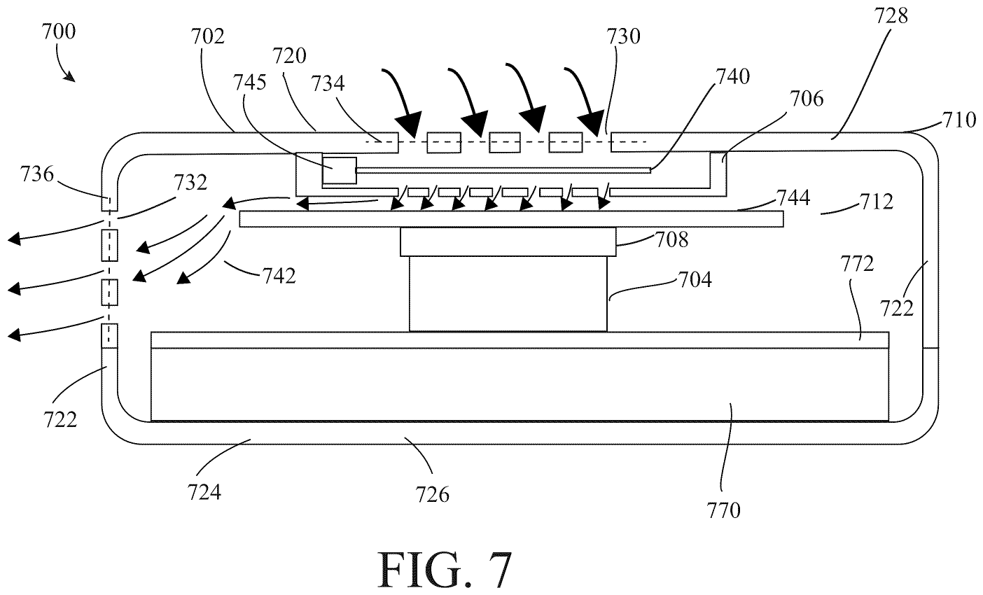

FIG. 7 shows a schematic sectional view of a further example handheld device having a vibrational membrane. In a similar way to that described in connection with FIGS. 1B, 1C, and 2 above, a handheld device 700 of FIG. 7 may include a casing 702, a device package 704, and a cooling assembly 706. The casing 702 may have an air inlet opening 730 and an air outlet opening 732 disposed therethough. The casing 702 may comprise a display side 720, a backside 724 opposite the display side 720, and sidewalls 722 connecting the display side 720 and the backside 724 to collectively define a casing wall 710 having a casing volume 712 therewithin.

Different from FIGS. 1B, 1C, and 2, the device package 704 and the cooling assembly 706 may both be disposed within the casing volume 712 (i.e., the casing volume is not divided into a cooling volume and a device volume). Similarly to FIGS. 1B, 1C, and 2, the cooling assembly 706 may be attached to the casing wall 710 and disposed within the casing volume 712. The cooling assembly 706 may include a vibrational membrane 740, attached to a transducer 745, arranged to create a cooling airflow 742 within the casing volume 712 by drawing air through the air inlet opening 730.

The air inlet opening 730 includes a gas-permeable membrane 734. Such a gas permeable membrane may allow the passage of gases but not permit the passage of liquids, such as water, therethrough and thus may be waterproof. As a result, air may be permitted to enter the cooling assembly 706 and pass through the casing 702 of the device 700 to allow cooling, but liquids such as water are prevented from entering the device to alleviate the risk of water damage to the device 700 occurring. Similarly, the air outlet opening 732 includes a gas-permeable membrane 736.

The handheld device 700 may include a battery 770 which may be a lithium ion battery or other similar battery. The device package 704 of the handheld device may be attached to a PCB 772.

As shown in FIG. 7, and different from that shown in FIGS. 1B, 1C, and 2, the device package 704 includes a heatsink 744 attached to and in thermal contact with the device package. The cooling airflow 742 within the device 700 is such that that the heatsink 744 is in thermal contact with the cooling airflow 742 and thus the cooling airflow 742 transfers heat away from the device package 704 by way of the heatsink 744. A thermal interface material 708 may be provided between the device package 704 and the heatsink 744 and is in thermal contact with both the device package 704 and the heatsink 744.

In a similar way to that shown in FIGS. 1B, 1C, and 2, the casing 702 may be formed of a first casing part 728 which includes the display side 720 of the casing 702 and a second casing part 726 which includes the backside 724 of the casing 702.

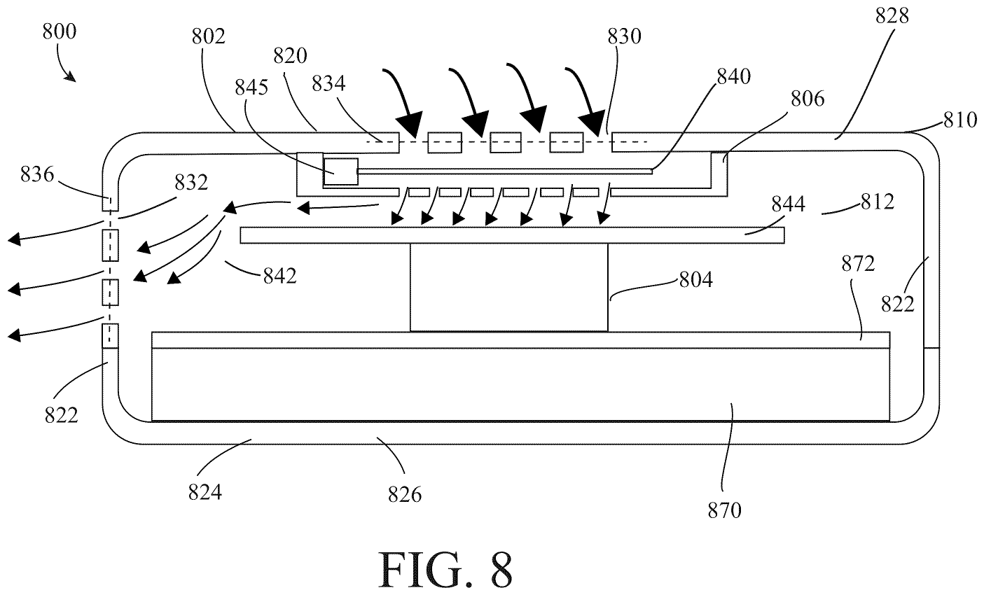

FIG. 8 shows a schematic sectional view of another example handheld device having a vibrational membrane. In FIG. 8, a handheld device 800, which is similar to that shown in FIGS. 1B, 1C, 2, and 7, may include a casing 802, a device package 804, and a cooling assembly 806. Similar to that described herein, casing 802 may have an air inlet opening 830 and an air outlet opening 832 disposed therethough. The casing 802 may comprise a display side 820, a backside 824 opposite the display side 820, and sidewalls 822 connecting the display side 820 and the backside 824 to collectively define a casing wall 810 having a casing volume 812 therewithin.

In a similar way to the handheld device 700 of FIG. 7, the device package 804 and the cooling assembly 806 may be disposed within the casing volume 812. The cooling assembly 806 may be attached to the casing wall 810 and disposed within the casing volume 812. As described herein, the cooling assembly 806 may include a vibrational membrane 840, attached to a transducer 845, arranged to create a cooling airflow 842 within the casing volume 812 by drawing air through the air inlet opening 830, and the device package 804 includes a heatsink 844 attached to and in thermal contact with the device package 804. The cooling airflow 842 within the device 800 is such that that the heatsink 844 is in thermal contact with the cooling airflow 842 and thus the cooling airflow 842 transfers heat away from the device package 804 by way of the heatsink 844.

In a similar way to that shown in FIGS. 1B, 1C, 2, and 7, the casing 802 may be formed of a first casing part 828 which includes the display side 820 of the casing 802 and a second casing part 826 which includes the backside 824 of the casing 802.

Similarly to that described herein, the air inlet opening 830 includes a gas-permeable membrane 834. Such a gas permeable membrane may allow the passage of gases but not permit the passage of liquids, such as water, therethrough and thus may be waterproof. As a result, air may be permitted to enter the cooling assembly 806 and pass through the casing 802 of the device 800 to allow cooling, but liquids such as water are prevented from entering the device to alleviate the risk of water damage to the device 800 occurring. Similarly, the air outlet opening 832 includes a gas-permeable membrane 836.

The handheld device 800 may include a battery 870 which may be a lithium ion battery or other similar battery. The device package 804 of the handheld device may be attached to a PCB 872.

However, different from that shown in FIG. 7, the heatsink 844 is in direct contact with the device package 804, without the use of an intervening material such as a thermal interface material or thermal adhesive. In some examples, the heatsink 844 may directly bonded to the semiconductor device 804. This does not involve the use of an intervening adhesive, and may employ direct bonding techniques understood in the art and as described herein.

The heatsink 844 and a backside of the semiconductor device 804 may be in direct contact. For example, in some embodiments, one or both of the heatsink 844 and the backside of the semiconductor device 804 may comprise a dielectric material layer, e.g., a first dielectric material layer and a second dielectric material layer respectively, and the heatsink 844 is directly bonded to the backside of the semiconductor device 804 through bonds formed between the dielectric material layers. In some embodiments, one of the heatsink 844 or the backside of the semiconductor device 804 may comprise a thin bonding dielectric layer (e.g., silicon nitride, etc.) and other element(s) may not include any such explicit bonding dielectric layer (or can have only native oxide layer). Here, the first and second dielectric material layers may be continuous layers, but it will be understood that one or both of the layers may not be continuous. For example, the first dielectric material layer may be disposed only on lower surfaces of the heatsink 844 facing the backside of the semiconductor device 804.

Beneficially, directly bonding the heatsink 844 to the semiconductor device 804, as described above, reduces the thermal resistance therebetween and increases the efficiency of heat transfer from the semiconductor device 804 to the heatsink 844.

In some embodiments, the heatsink 844 may be attached to the semiconductor device 804 using a hybrid bonding technique, where bonds are formed between the dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometer or less, 1 micrometer or less, 500 nm or less, such as 100 nm or less, or 50 nm or less. The dielectric layer material and thickness may be optimized for lower thermal resistance between the semiconductor device 804 and the heatsink 844.

If the heatsink 844 is attached to the semiconductor device 804 by direct bonding, this may include forming dielectric layers on one or both the of the heatsink 844 which may be a first substrate and the chip 804 which may be a second substrate, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N2, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH2 groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, a method may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBIR, each of which are commercially available from Adeia Holding Corp., San Jose, CA, USA.

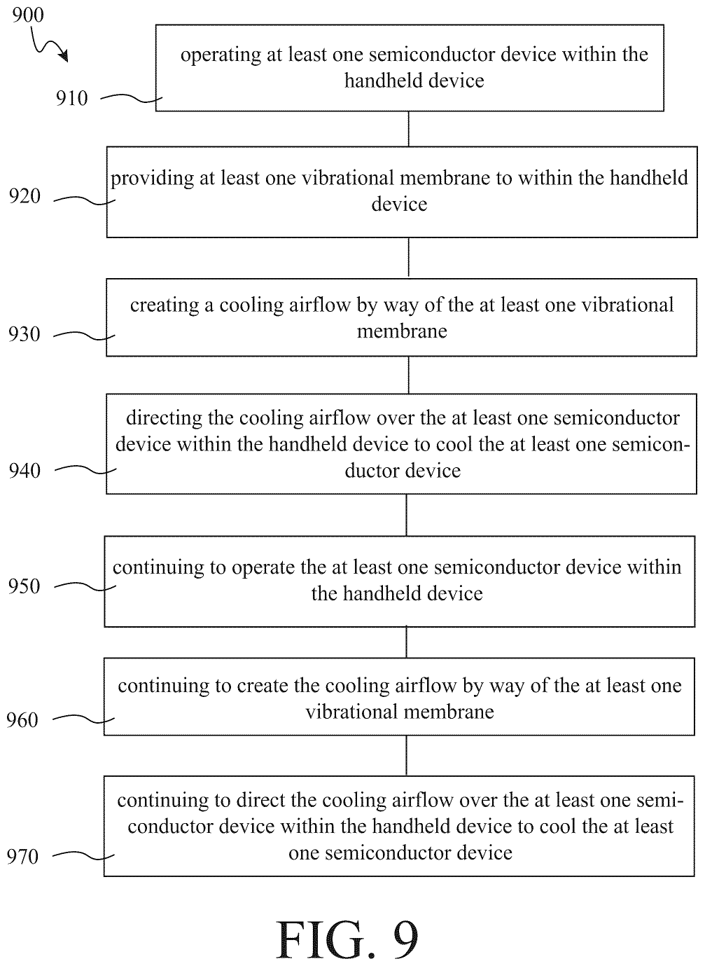

FIG. 9 shows a method 900 that can be used to cool a handheld device including cooling assemblies as described herein. The method 900 begins at block 910, at which the semiconductor device is operated within the handheld device.

At block 920, at least one vibrational membrane is provided within the handheld device.

At block 930, the at least one vibrational membrane is used to create a cooling airflow.

At block 940, the cooling airflow is directed over the at least one semiconductor device, within the handheld device, to cool the at least one semiconductor device.

At block 950, the at least one semiconductor device within the handheld device is continued to be operated.

At block 960, the at least one vibrational membrane is continued to be used to create a cooling airflow. At block 970, the cooling airflow is continued to be directed over the at least one semiconductor device, within the handheld device, to continue to cool the at least one semiconductor device.

The method described above advantageously provides for integrated cooling assemblies that increased convective heat transfer from a semiconductor device to a coolant fluid such as air, which facilitates an increase in power density of advanced device packages.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. A handheld device comprising:
a casing;
a device package; and
a cooling assembly, wherein:
the casing has an air inlet opening and an air outlet opening disposed therethough, the casing comprising a display side, a backside opposite the display side, and sidewalls connecting the display side and the backside to collectively form a casing wall defining a casing volume therewithin;
the casing volume is split into a device volume and a cooling volume, the cooling volume separated from the device volume by a dividing surface, the cooling volume fluidly connected to the air inlet opening and the air outlet opening;
the device package is disposed within the device volume;
the cooling assembly is attached to the casing wall and disposed within the cooling volume, the cooling assembly comprising a vibrational membrane arranged to create a cooling airflow within the cooling volume by drawing air through the air inlet opening; and
the device package includes a thermal interface material in thermal contact with the device package and the dividing surface, the dividing surface exposed to and in thermal contact with the cooling airflow.

2. The handheld device of claim 1, wherein the air inlet opening, the cooling assembly, and the air outlet opening collectively define a cooling airflow path.

3. The handheld device of claim 1, wherein the cooling assembly includes a further air inlet aligned with the air inlet opening in the casing.

4. The handheld device of claim 1, wherein the cooling assembly includes a further air outlet in fluid communication with the cooling volume.

5. The handheld device of claim 1, wherein the vibrational membrane is actuated by a piezoelectric transducer.

6. The handheld device of claim 1, wherein the vibrational membrane is actuated by a magnetostrictive transducer.

7. The handheld device of claim 1, wherein the vibrational membrane is an elongate member.

8. The handheld device of claim 1, wherein the vibrational membrane includes apertures formed therethrough.

9. The handheld device of claim 8, wherein the vibrational membrane directs compressed streams of gas towards the dividing surface to cool the device package.

10. The handheld device of claim 1, wherein the vibrational membrane comprises more than one vibrational membrane.

11. The handheld device of claim 1, wherein the cooling assembly is formed as part of the casing.

12. The handheld device of claim 1, wherein the cooling airflow within the casing volume is within the cooling volume.

13. The handheld device of claim 12, wherein the cooling airflow passes over the dividing surface.

14. The handheld device of claim 1, wherein the dividing surface extends between the sidewalls of the casing.

15. (canceled)

16. The handheld device of claim 1, wherein the cooling volume is not in fluid communication with the device volume.

17. The handheld device of claim 1, wherein the air inlet of the casing and the air outlet of the casing both include a gas-permeable membrane.

18-20. (canceled)

21. The handheld device of claim 1, wherein the handheld device is a handheld communications device.

22-25. (canceled)

26. A handheld device comprising:
a casing;
a device package; and
a cooling assembly, wherein:
the casing has an air inlet opening and an air outlet opening disposed therethough, the casing comprises a display side, a backside opposite the display side, and sidewalls connecting the display side and the backside to collectively define a casing wall having a casing volume therewithin;
the casing volume is split into a device volume and a cooling volume, the cooling volume separated from the device volume by a divider, the device volume including the air inlet opening and the cooling volume including the air outlet opening;
the cooling volume is disposed within the device volume, such that the divider substantially encloses the cooling volume within the device volume, and the cooling assembly is disposed within the cooling volume and in thermal contact with the divider;
the cooling assembly comprises a vibrational membrane;
the device package is disposed within the device volume, the device package comprising a heat spreader in thermal contact with the divider;
the cooling volume is in fluid communication with the device volume through at least one opening in the divider, and the air outlet opening provides a fluid pathway out of the casing volume; and
the cooling assembly is arranged to create a cooling airflow within the casing volume by drawing air through the air inlet opening, through the at least one opening in the divider and through the air outlet opening, to cool the device package.

27-37. (canceled)

38. The handheld device of claim 26, wherein the handheld device is a handheld communications device.

39-42. (canceled)

43. A handheld device comprising:
a casing;
a device package; and
a cooling assembly, wherein:
the casing has an air inlet opening and an air outlet opening disposed therethough, the casing comprising a display side, a backside opposite the display side, and sidewalls connecting the display side and the backside to collectively define a casing wall having a casing volume therewithin;
the device package and the cooling assembly are disposed within the casing volume;
the cooling assembly is attached to the casing wall and disposed within the casing volume, the cooling assembly comprising a vibrational membrane arranged to create a cooling airflow within the casing volume by drawing air through the air inlet opening; and
the device package includes a heatsink attached to and in thermal contact therewith, the heatsink in thermal contact with the cooling airflow.

44-47. (canceled)
